(19) United States
(12) Patent Application Publication
(10) Pub. No.: US 2026/0190767 A1
(43) Pub. Date: Jul. 2, 2026

(54) DISPLAY DEVICE

(71) Applicant: LG Display Co., Ltd., Seoul (KR)

(72) Inventors: Jungkyu PARK, Seoul (KR); TaeWoo KIM, Paju-si (KR); JunHyung KIM, Paju-si (KR); Kyungjae PARK, Incheon (KR); GeunChang PARK, Paju-si (KR)

(73) Assignee: LG Display Co., Ltd., Seoul (KR)

(21) Appl. No.: 19/431,757

(22) Filed: Dec. 23, 2025

(30) Foreign Application Priority Data
Dec. 31, 2024 (KR) 10-2024-0202947

(51) Int. Cl. H10K 59/80; H10K 102/00

(52) U.S. Cl. CPC H10K 59/8721; H10K 2102/311

(57) ABSTRACT

A display device can include a display panel having a non-bending area and a bending area adjacent to the non-bending area, and a support plate disposed below the display panel. The support plate includes a first part corresponding to the non-bending area and a second part corresponding t o the bending area. The second part of the metal plate includes a plurality of opening portions spaced part from each other, and the first part of the metal plate includes a plurality of pattern portions in an area of the first part of the metal plate adjacent to the second part of the metal plate.

### CROSS-REFERENCE TO RELATED APPLICATIONS

This application claims priority to Korean Patent Application No. 10-2024-0202947, filed on Dec. 31, 2024, in the Korean Intellectual Property Office, the entire disclosure of which is hereby expressly incorporated by reference for all purposes, as if fully set forth herein.

### BACKGROUND

### Technical Field

The present disclosure relates to a display device, and more particularly, for example, without limitation, to a display device with improved display quality.

### Description of the Related Art

Recently, display devices, which process and display a large amount of information, have been rapidly developed in accordance with the full-fledged entry into the information era. As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In particular, flexible display devices, which are manufactured to be able to display images even when being bent or folded like paper, have attracted attention as next-generation display devices. The flexible display devices can be classified into an unbreakable display device having high durability and using a plastic thin-film transistor substrate instead of a glass substrate, a bendable display device capable of being bent without being broken, a rollable display device capable of being rolled circularly, and a foldable device capable of being folded. These flexible display devices can have spatial utilization and advantageous interior and design and be applied to various application fields.

The description provided in the background section should not be assumed to be prior art merely because it is mentioned in or associated with the background section. The background section can include information that describes one or more aspects of the subject technology.

### SUMMARY OF THE DISCLOSURE

It is newly recognized by inventors of the present disclosure that, since a flat shape of a central portion of a display device including a bending area needs to be maintained, and a bent shape of a lateral portion including a corner needs to be maintained, the display panel cannot be smoothly contracted because of contraction deformation occurring on a structure for supporting a shape of a bending area of the display panel, which can cause a problem in which creases are formed, damage occurs, and display quality of the display panel deteriorates.

An aspect of the present disclosure is to provide a display device capable of reducing a rapid change in rigidity occurring at a boundary between a bending area and a non-bending area.

Another aspect of the present disclosure is to provide a display device capable of improving visibility at a boundary between a bending area and a non-bending area.

Additional features and aspects of the disclosure are set forth in part in the description that follows and in part will become apparent from the description or can be learned by practice of the inventive concepts provided herein. Other features and aspects of the inventive concepts can be realized and attained by the structures pointed out in the present disclosure, or derivable therefrom, and the claims hereof as well as the appended drawings.

To achieve these and other aspects of the inventive concepts, as embodied and broadly described herein, there is provided a display device. The display device according to aspects of the present disclosure includes a display panel comprising a non-bending area and a bending area and a metal plate disposed below the display panel. The bending area includes a first bending area corresponding to a lateral portion of the non-bending area and a second bending area corresponding to a corner of the non-bending area. The metal plate includes a first part disposed in the non-bending area and a second part disposed in the bending area. A plurality of first pattern portions and a plurality of second pattern portions are disposed in a part of the first part and spaced apart from one another. A plurality of first opening portions and a plurality of second opening portions are disposed in the second part.

In another aspect of the present disclosure, there is provided a display device. The display device includes a display panel comprising a non-bending area and a bending area adjacent to the non-bending area and a support plate disposed below the display panel. The support plate includes a first part corresponding to the non-bending area and a second part corresponding t o the bending area. The second part includes a plurality of opening portions spaced part from each other, and the first part includes a plurality of pattern portions in an area of the first part adjacent to the second part.

Other detailed matters of the example embodiments of the present disclosure are included in the detailed description and the drawings.

According to the embodiments of the present disclosure, the plurality of pattern portions is disposed on the metal plate in the non-bending area adjacent to the bending area, which can suppress a transformation of the metal plate caused by a rapid change in rigidity at the boundary between the bending area and the non-bending area.

According to the embodiments of the present disclosure, the plurality of pattern portions includes the first pattern portion, the second pattern portion, and the third pattern portion disposed to be spaced apart from one another, which can inhibit the plurality of pattern portions of the metal plate from being visually recognized.

According to the embodiments of the present disclosure, the display device includes the metal plate including the plurality of pattern portions, such that components for supporting the display panel and ensuring visibility are not needed, which can provide a lightweight display device.

Aspects of the present disclosure are not limited to the above-mentioned aspects, and other aspects, which are not mentioned above, can be clearly understood by those skilled in the art from the following descriptions.

The effects of the present disclosure are not limited to the aforementioned effects, and other effects, which are not mentioned above, will be apparently understood to a person having ordinary skill in the art from the following description.

The aspects to be achieved by the present disclosure, the means for achieving the aspects, and the effects of the present disclosure described above do not specify essential features of the claims, and, thus, the scope of the claims is not limited to the disclosure of the present disclosure.

It is to be understood that both the foregoing general description and the following detailed description are example and explanatory and are intended to provide further explanation of the inventive concepts as claimed.

### BRIEF DESCRIPTION OF THE DRAWINGS

The accompanying drawings, that can be included to provide a further understanding of the disclosure and can be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is a schematic perspective view of a display device according to an example embodiment of the present disclosure;

FIG. 2 is an enlarged view of area X in FIG. 1;

FIG. 3 is a schematic exploded perspective view of the display device according to the example embodiment of the present disclosure;

FIG. 4 is an enlarged view of a partial area of a metal plate of the display device according to the example embodiment of the present disclosure;

FIG. 5 is a cross-sectional view taken along line A-B in FIG. 3;

FIG. 6 is a cross-sectional view taken along line C-D in FIG. 3;

FIG. 7 is an enlarged view of area Y in FIG. 4;

FIG. 8 is an enlarged view of area Z in FIG. 4;

FIG. 9 is a view illustrating a change in rigidity applied to a boundary between a first part and a second part of a metal plate of a display device according to a comparative example; and

FIG. 10 is a view illustrating a change in rigidity applied to a boundary between a first part and a second part of a metal plate of the display device according to the example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Advantages and features of the present disclosure and a method of achieving the advantages and features will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure. Any implementation described herein as an “example” is not necessarily to be construed as preferred or advantageous over other implementations.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with a more limiting term such as “only”. An element described in the singular form is intended to include a plurality of elements, and vice versa, unless the context clearly indicates otherwise.

In construing an element, the element is construed as including an ordinary error range or tolerance range although there is no explicit description of such an error or tolerance range.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts can be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

When an element or layer is disposed “on” another element or layer, another layer or another element can be interposed directly on the other element or therebetween.

Although the terms “first”, “second”, “A”, “B”, “(a)”, “(b)” and the like are used for describing various components, the essence, sequence, order, or number of these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

In the description of embodiments, when a structure is described as being positioned “on or above” or “under or below” another structure, this description should be construed as including a case in which the structures contact each other as well as a case in which a third structure is disposed therebetween. A size and a thickness of each component illustrated in the drawing are illustrated for convenience of description, and the present disclosure is not limited to the size and the thickness of the component illustrated.

The terms “first direction”, “second direction”, “third direction”, “row direction”, “column direction”, “X-axis direction”, “Y-axis direction”, and “Z-axis direction” should not be interpreted solely as geometric relationships perpendicular to each other, but can indicate broader directionality within the range where the configuration of the present disclosure can function.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may” and vice versa.

Hereinafter, a display device according to various example embodiments of the present disclosure will be described in detail with reference to accompanying drawings. Further, all the components of each display device according to all embodiments of the present disclosure are operatively coupled and configured.

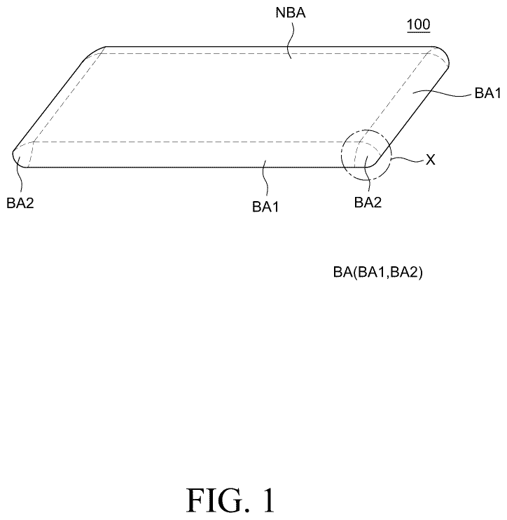

FIG. 1 is a schematic perspective view of a display device according to an embodiment of the present disclosure.

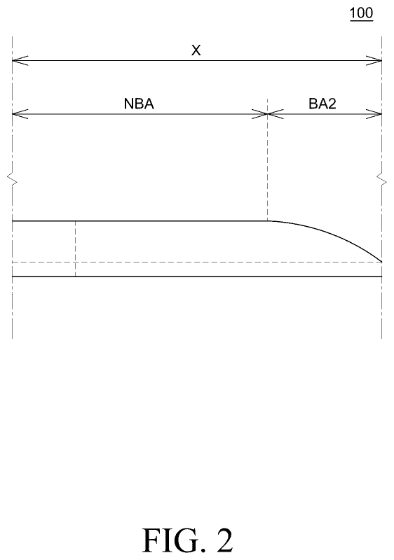

FIG. 2 is an enlarged view of area X in FIG. 1.

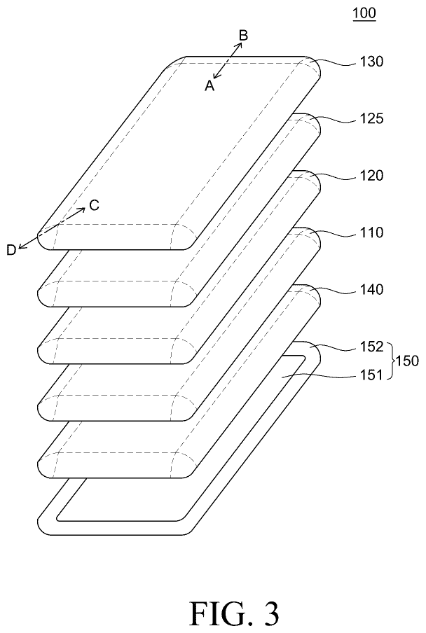

FIG. 3 is a schematic exploded perspective view of the display device according to the embodiment of the present disclosure.

With reference to FIGS. 1 to 3, a display device 100 according to an embodiment of the present disclosure includes one or more of a display panel 110, a polarizing film 120, a bonding layer 125, a cover window 130, a backplate 140, and a metal plate 150.

The display panel 110 is a panel for implementing images. Display elements for implementing images, circuit parts for operating the display elements, and the like can be disposed on the display panel 110. For example, in case that the display device 100 is an organic light-emitting display device, the display elements can include an organic light-emitting element.

Hereinafter, for convenience of description, it is assumed that the display device 100 according to the embodiment of the present disclosure is a display device including an organic light-emitting element. However, the present disclosure is not limited thereto, and various other types of display devices such as a liquid crystal display (LCD) device and inorganic light-emitting display device can also be used as the display device of the present disclosure.

The circuit part can include various thin-film transistors, capacitors, lines, drive ICs, and the like for operating the organic light-emitting elements.

For example, the circuit parts can include various components such as thin-film driving transistors, thin-film switching transistors, storage capacitors, gate lines, data lines, gate driver ICs, and data driver ICs. However, the present disclosure is not limited thereto.

The display panel 110 is made by forming the thin-film driving transistors and the light-emitting elements on a flexible substrate and encapsulating the flexible substrate with an encapsulation part. The display panel 110 can include a flexible substrate having a very small thickness for implementing flexibility, and a display element disposed on the flexible substrate.

The flexible substrate can be made of an insulating material having flexibility. For example, the flexible substrate can be an insulating plastic substrate made of a material selected from polyimide, polyether sulfone, polyethylene terephthalate, and polycarbonate. In another example, the flexible substrate can include a plastic material having flexibility, such as any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC), polyvinyl alcohol(PVA), polyimide(PI), and polystyrene(PS), but the example embodiments of the present disclosure are not limited thereto.

With reference to FIGS. 1 to 3, the display panel 110 includes a non-bending area NBA and bending areas BA.

The non-bending area NBA is an area in which the display panel 110 is kept in a flat state. The entire non-bending area NBA can be configured as a display area. Alternatively, the non-bending area NBA can include a display area, and a non-display area adjacent to the display area. However, the present disclosure is not limited thereto.

The bending areas BA are areas in which the display panel 110 is bent.

The bending areas BA can be areas extending from lateral portions and corners of the non-bending area NBA.

All or some of the bending areas BA can be configured as the display areas, and a partial area of the bending area BA can be configured as the non-display area. However, the present disclosure is not limited thereto.

The bending areas BA can include first bending areas BA1 and second bending areas BA2.

The first bending area BA1 can be an area extending from the lateral portion of the non-bending area NBA.

The second bending area BA2 can be an area extending from the corner of the non-bending area NBA.

Specifically, in case that the non-bending area NBA has a quadrangular shape in a plan view, the first bending areas BA1 can be areas extending from four sides of the non-bending area NBA and bent at a particular radius of curvature.

In addition, in case that the non-bending area NBA has a quadrangular shape in a plan view, the second bending areas BA2 can be areas extending from four corners and bent at a particular radius of curvature.

The first bending areas BA1 and the second bending areas BA2 can be disposed to surround the non-bending area NBA, but the present disclosure is not limited thereto.

In addition, the first bending areas BA1 and the second bending areas BA2 can be disposed alternately. For example, one second bending area BA2 can be disposed between two first bending areas BA1, and one first bending area BA1 can be disposed between two second bending areas BA2.

In addition, the display device 100 according to the embodiment of the present disclosure can include the display area and the non-display area.

The display area is an area in which a plurality of pixels is disposed to substantially display images.

The non-display area can be disposed to surround the display area.

The non-display area is an area in which no image is substantially displayed. Various lines, a drive IC, a printed circuit board, and the like are disposed to operate the pixel and a drive circuit disposed in the display area. For example, various ICs, such as a gate driver IC and a data driver IC, a VSS line, and the like can be disposed in the non-display area.

Assuming that an image display surface of the display device 100 is directed forward, the polarizing film 120 can be disposed on a display surface of the display panel 110 in a direction toward the display surface of the display device 100.

The polarizing film 120 can serve to polarize, at a polarization angle, light emitted from the display panel 110.

The polarizing film 120 discharges the light, which is polarized at a polarization angle, to the outside. The polarizing film 120 can include a function of blocking the reflection of light beams, except for the light beams polarized at a polarization angle, among light beams from the outside.

In addition, FIG. 3 illustrates that the display device 100 includes the polarizing film 120. However, the polarizing film 120 can be excluded in accordance with design.

The bonding layer 125 can be disposed on the polarizing film 120. The bonding layer 125 can include a transparent bonding material with high light transmittance.

The cover window 130 can be disposed on the bonding layer 125.

The cover window 130 can serve to protect the display panel 110 from external impact and suppress the occurrence of damage such as scratches.

The cover window 130 can be made of a flexible plastic-based material that is bendable to implement the thin, flexible display device 100.

In addition, a touch panel, which selectively implements a touch sensor, as necessary, can be disposed between the display panel 110 and the cover window 130. In addition, the touch panel can be integrated into the display panel 110 as one or more components of the display panel 110.

A rear surface of the display panel 110 can include the backplate 140 configured to support the display panel 110. The backplate 140 can be referred to as a top plate because the backplate 140 is one of the two plates disposed on the rear surface of the display panel 110, and the backplate 140 is disposed at the upper side. The backplate 140 can be made of a polyethylene terephthalate (PET) based material. However, the present disclosure is not limited thereto, and the backplate 140 can be omitted when necessary.

The backplate 140 can maintain a constant curvature of the display panel 110 and suppress the occurrence of a wrinkle on a top surface of the display panel 110 when the display device 100 is bent.

In addition, the backplate 140 can be disposed between the display panel 110 and the metal plate 150 and inhibit a plurality of opening portions of the metal plate 150 from being transferred to a display screen or suppress distortion of the display screen caused by the plurality of opening portions.

The metal plate 150 configured to support the display panel 110 can be disposed on the rear surface of the backplate 140.

The metal plate 150 can serve to support a flexible substrate, which constitutes the display panel 110, so that the flexible substrate does not sag. The metal plate 150 can serve to protect the constituent elements disposed on the flexible substrate from outside moisture, heat, impact, or the like.

The metal plate 150 can be referred to as a bottom plate because the metal plate 150 is one of the two plates disposed on the rear surface of the display panel 110, and the metal plate 150 is disposed at the lower side.

The metal plate 150 can be made of a material such as stainless steel (SUS) and amorphous metal having rigidity to maintain a shape of the display panel 110, but the present disclosure is not limited thereto. For example, the metal plate 150 can be referred to as a support plate or a plastic plate, since it can include a plastic material having rigidity enough to support the display panel 110.

The metal plate 150 can include a first part 151 and a second part 152.

The first part 151 of the metal plate 150 can be a part corresponding to the non-bending area NBA of the display device 100.

The second part 152 of the metal plate 150 can be a part corresponding to the bending area BA of the display device 100. Specifically, the second part 152 of the metal plate 150 can correspond to the first bending area BA1 and the second bending area BA2 of the display device 100.

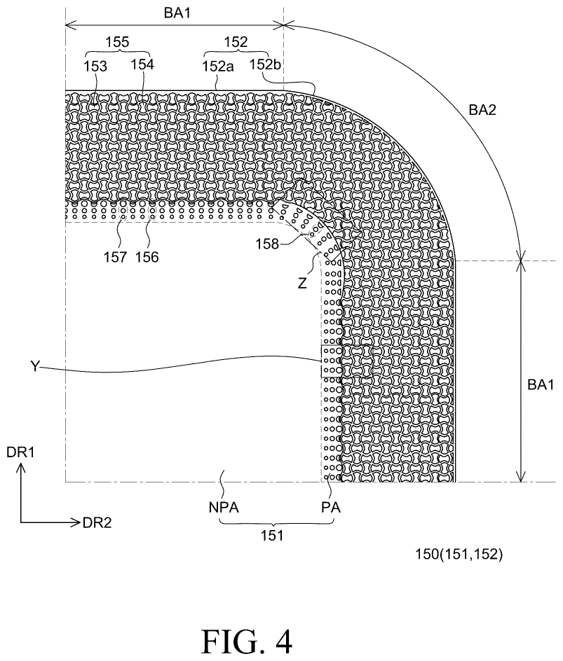

A structure of the metal plate 150 of the display device 100 according to the embodiment of the present disclosure will be described below with reference to FIG. 4.

FIG. 4 is an enlarged view of a part of the metal plate included in the display device according to the embodiment of the present disclosure.

With reference to FIG. 4, the metal plate 150 of the display device 100 can include the first part 151 and the second part 152.

The first part 151 of the metal plate 150 can be a part corresponding to the non-bending area NBA of the display device 100.

Therefore, the first part 151 of the metal plate 150 can include an area kept in a flat state. For example, the first part 151 of the metal plate 150 can include an area that is not bent at a particular radius of curvature.

The first part 151 of the metal plate 150 can include a pattern area PA and a non-pattern area NPA.

The pattern area PA of the first part 151 of the metal plate 150 can be disposed between the second part 152 of the metal plate 150 and the non-pattern area NPA of the first part 151 of the metal plate 150.

A plurality of pattern portions 156, 157, and 158 can be disposed in the pattern area PA of the first part 151 of the metal plate 150.

Specifically, the plurality of first pattern portions 156 and the plurality of second pattern portions 157 can be disposed in an area of the pattern area PA of the first part 151 of the metal plate 150 that is adjacent to the first bending area BA1.

The plurality of first pattern portions 156 and the plurality of second pattern portions 157 can each include a plurality of patterns.

At least one of the plurality of patterns included in the plurality of first pattern portions 156 and at least one of the plurality of patterns included in the plurality of second pattern portions 157 can have different shapes in a plan view.

The plurality of patterns included in the plurality of first pattern portions 156 can be arranged to be spaced apart from one another in one direction (for example, in a direction from the first bending area to the non-bending area), and the plurality of patterns included in the plurality of second pattern portions 157 can be arranged to be spaced apart from one another in one direction (for example, in a direction from the first bending area to the non-bending area).

For example, the plurality of patterns included in the plurality of first pattern portions 156 can be arranged to be spaced apart from one another in a first direction DR1 or a second direction DR2 intersecting the first direction DR1, and the plurality of patterns included in the plurality of second pattern portions 157 can be arranged to be spaced apart from one another in the first direction DR1 or the second direction DR2.

The plurality of first pattern portions 156 and the plurality of second pattern portions 157 can be disposed alternately. For example, the plurality of first pattern portions 156 and the plurality of second pattern portions 157 can be disposed alternately in the second direction DR2 or the first direction DR1.

The plurality of patterns included in the plurality of first pattern portions 156 and the plurality of patterns included in the plurality of second pattern portions 157 can be hole patterns or opening patterns. However, the present disclosure is not limited thereto.

In addition, a plurality of third pattern portions 158 can be disposed in an area of the pattern area PA of the first part 151 of the metal plate 150 that is adjacent to the second bending area BA2.

The plurality of third pattern portions 158 can be disposed at the corner of the first part 151.

The plurality of third pattern portions 158 can include a plurality of patterns.

At least one of the plurality of patterns included in the plurality of third pattern portions 158 and at least one of the plurality of patterns included in the plurality of first pattern portions 156 and the plurality of second pattern portions 157 can have different shapes in a plan view.

The plurality of patterns included in the plurality of third pattern portions 158 can be disposed to be spaced apart from one another in a direction between the first direction DR1 and the second direction DR2.

The plurality of first pattern portions 156, the plurality of second pattern portions 157, and the plurality of third pattern portions 158 disposed in the pattern area PA of the first part 151 of the metal plate 150 are disposed adjacent to the bending area BA and serve to inhibit the metal plate 150 from being wrinkled by the occurrence of compressive stress applied because of the bending area BA.

Specifically, the plurality of first pattern portions 156, the plurality of second pattern portions 157, and the plurality of third pattern portions 158 disposed in the pattern area PA of the first part 151 of the metal plate 150 can each serve to mitigate a rapid change in rigidity of the metal plate 150 occurring at a boundary between the first part 151 and the second part 152.

For example, it is possible to suppress the occurrence of a defect of the metal plate 150 caused by compressive stress applied between the first part 151 of the metal plate 150, which is a flat section, and the second part 152 that is a bending section.

The second part 152 of the metal plate 150 can be a part corresponding to the bending area BA of the display device 100.

Therefore, the second part 152 of the metal plate 150 can include an area that is bent at a particular radius of curvature.

For example, a top surface of the metal plate 150 with respect to the second part 152 can include a bending section bent at a particular radius of curvature.

The second part 152 of the metal plate 150 can include first sub-areas 152a and second sub-areas 152b.

The first sub-area 152a of the second part 152 can be disposed to correspond to the first bending area BA1 of the bending area BA.

In addition, the second sub-area 152b of the second part 152 can be disposed to correspond to the second bending area BA2 of the bending area BA.

Therefore, the first sub-areas 152a and the second sub-areas 152b can be disposed alternately. For example, one second sub-area 152b can be disposed between two first sub-areas 152a, and one first sub-area 152a can be disposed between two second sub-areas 152b.

The second part 152 of the metal plate 150 can extend from the first part 151 and be integrated with the first part 151.

Specifically, in case that the first part 151 of the metal plate 150 has a quadrangular shape in a plan view, the first sub-areas 152a of the second part 152 of the metal plate 150 can extend from four sides of the first part 151 of the metal plate 150.

In addition, in case that the first part 151 of the metal plate 150 has a quadrangular shape in a plan view, the second sub-areas 152b of the second part 152 of the metal plate 150 can extend from the corners of the first part 151 of the metal plate 150.

The first sub-area 152a of the second part 152 of the metal plate 150 can be connected to the first part 151 of the metal plate 150. Specifically, the first sub-area 152a of the second part 152 of the metal plate 150 can be disposed adjacent to the pattern area PA of the metal plate 150 in which the plurality of first pattern portions 156 and the plurality of second pattern portions 157 are disposed.

The second sub-area 152b of the second part 152 of the metal plate 150 can be disposed adjacent to the pattern area PA of the metal plate 150 in which the plurality of third pattern portions 158 are disposed.

In addition, the second part 152 of the metal plate 150 is bent at a particular radius of curvature, such that stress can be applied to the boundary between the first part 151 and the second part 152 of the metal plate 150.

Specifically, in case that the flat metal plate is bent to have a curved surface, contraction deformation can occur in a bending direction.

In particular, a contraction deformation amount can be large at a boundary between the bending area BA and the non-bending area NBA. Therefore, compressive stress can occur in several directions at the boundary between the first part 151 and the second part 152 of the metal plate 150.

In addition, in case that only a plurality of first opening portions 153 and a plurality of second opening portions 154 are disposed only in the second part 152 of the metal plate 150, a rapid change in rigidity can occur at the boundary between the first part 151 and the second part 152 of the metal plate 150.

In this case, because the boundary between the first part 151 and the second part 152 of the metal plate 150 cannot be smoothly contracted, there is a problem in that the boundary between the first part 151 and the second part 152 of the metal plate 150 is wrinkled, or the display panel 110 disposed on the metal plate 150 is damaged at the boundary between the bending area BA and the non-bending area NBA due to the deformation transferred from the wrinkled boundary of the metal plate 150.

In addition, in case that the metal plate 150 is wrinkled, there is a problem in that the wrinkle is visually recognized, and the quality of the display device 100 deteriorates.

In case that a plurality of opening portions 155 are disposed only in the second part 152 of the metal plate 150, there is a problem in that lines are visually recognized at the boundary between the bending area BA and the non-bending area NBA.

Therefore, the display device 100 according to the embodiment of the present disclosure can include the plurality of pattern portions 156, 157, and 158 and the plurality of opening portions 155 in order to suppress a rapid change in rigidity of the metal plate 150 at the boundary between the first part 151 and the second part 152 of the metal plate 150. The opening portions 155 can also be referred to as pattern portions or hole portions, similar to the plurality of pattern portions 156, 157, and 158.

Specifically, the first and second sub-areas 152a and 152b of the second part 152 of the metal plate 150 can each include the plurality of opening portions 155.

The plurality of opening portions 155 can include the plurality of first opening portions 153 and the plurality of second opening portions 154.

The plurality of first opening portions 153 and the plurality of second opening portions 154 can be alternately disposed in the first direction DR1 and the second direction DR2. In addition, as shown in FIG. 4, the plurality of first opening portions 153 and the plurality of second opening portions 154 are basically aligned with each other in the first direction DR1 and the second direction DR2.

The structure of the display device 100 according to the embodiment of the present disclosure including the plurality of pattern portions 156, 157, and 158 and the plurality of opening portions 155 will be described specifically.

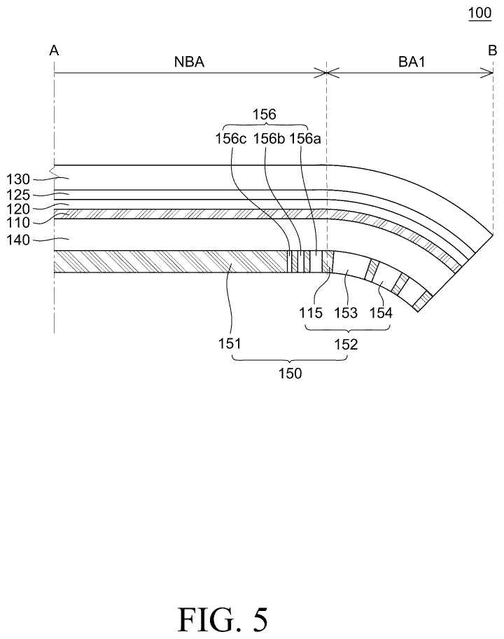

FIG. 5 is a cross-sectional view taken along line A-B in FIG. 3.

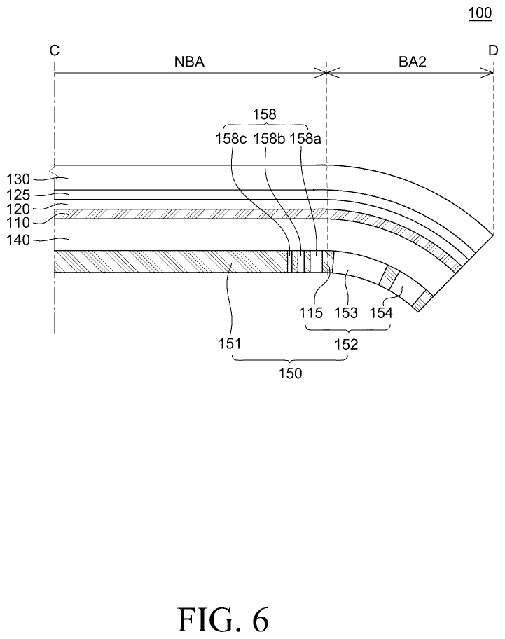

FIG. 6 is a cross-sectional view taken along line C-D in FIG. 3.

With reference to FIGS. 5 and 6, the display device 100 can include the backplate 140 disposed on the metal plate 150, the display panel 110 disposed on the backplate 140, the polarizing film 120 disposed on the display panel 110, the bonding layer 125 disposed on the polarizing film 120, and the cover window 130 disposed on the bonding layer 125.

The metal plate 150 can include the plurality of pattern portions 156 and 158 disposed in the non-bending area NBA.

Specifically, the first part 151 of the metal plate 150 can include the plurality of first pattern portions 156 and the plurality of third pattern portions 158.

The plurality of first pattern portions 156 and the plurality of third pattern portions 158 provided in the first part 151 of the metal plate 150 can each be a hole pattern.

The plurality of first pattern portions 156 can include a plurality of sub-patterns disposed to be spaced apart from one another. For example, the plurality of first pattern portions 156 can include first sub-patterns 156a, second sub-patterns 156b, and third sub-patterns 156c disposed to be spaced apart from one another.

In addition, the second pattern portions 157 disposed in the pattern area PA of the first part 151 of the metal plate 150 can also include a plurality of sub-patterns disposed to be spaced apart from one another, like the first pattern portions 156.

For example, like the first pattern portions 156, the plurality of second pattern portions 157 can include fourth sub-patterns, fifth sub-patterns, and sixth sub-patterns disposed to be spaced apart from one another.

The plurality of first pattern portions 156 can overlap the backplate 140, the display panel 110, the polarizing film 120, the bonding layer 125, and the cover window 130.

The plurality of third pattern portions 158 can include a plurality of sub-patterns disposed to be spaced apart from one another. For example, the plurality of third pattern portions 158 can include seventh sub-patterns 158a, eighth sub-patterns 158b, and ninth sub-patterns 158c disposed to be spaced apart from one another. It is to be noted that although it is shown in embodiments of the present disclosure that each of the first to third pattern portions includes three sub-patterns, the number or shape of the sub-patterns included in each of the first to third pattern portions is not limited thereto, and various other implementations are also possible when necessary.

In addition, the metal plate 150 can include the plurality of opening portions 155 disposed between the first bending area BA1 and the second bending area BA2.

Specifically, the second part 152 of the metal plate 150 can include the plurality of first opening portions 153 and the plurality of second opening portions 154 disposed in the first bending area BA1 and the second bending area BA2.

The plurality of first pattern portions 156 positioned in the first part 151 of the metal plate 150 can be disposed adjacent to the first bending area BA1.

Specifically, the first sub-pattern 156a of the first pattern portion 156 can be disposed to be closer to the first bending area BA1 than the second sub-pattern 156b of the first pattern portion 156 and the third sub-pattern 156c of the first pattern portion 156 to the first bending area BA1.

The second sub-pattern 156b of the first pattern portion 156 can be disposed to be closer to the first bending area BA1 than the third sub-pattern 156c of the first pattern portion 156 to the first bending area BA1.

The plurality of third pattern portions 158 positioned in the first part 151 of the metal plate 150 can be disposed adjacent to the second bending area BA2.

Specifically, the seventh sub-pattern 158a of the third pattern portion 158 can be disposed to be closer to the second bending area BA2 than the eighth sub-pattern 158b of the third pattern portion 158 and the ninth sub-pattern 158c of the third pattern portion 158 to the second bending area BA2.

In addition, the eighth sub-pattern 158b of the third pattern portion 158 can be disposed to be closer to the second bending area BA2 than the ninth sub-pattern 158c of the third pattern portion 158 to the second bending area BA2.

As described above, the plurality of first pattern portions 156 and the plurality of third pattern portions 158 are disposed in the first part 151 of the metal plate 150, such that compressive stress to be applied to the boundary between the first part 151 and the second part 152 of the metal plate 150 can be reduced, which can suppress the occurrence of a rapid change in rigidity of the metal plate 150.

In particular, the plurality of patterns included in the first pattern portion 156 and the third pattern portion 158 can divide and reduce the compressive stress applied to the first part 151 of the metal plate 150.

Therefore, the plurality of patterns included in the first pattern portion 156 and the third pattern portion 158 do not need to increase in size to reduce compressive stress applied to the first part 151 of the metal plate 150.

In case that the plurality of patterns included in the first pattern portion 156 and the third pattern portion 158 increase in sizes, the plurality of patterns can be visually recognized by a viewer. For this reason, there occurs a problem in that the display quality of the display device 100 deteriorates.

In the display device 100 according to the embodiment of the present disclosure, the plurality of patterns are included in the plurality of first pattern portions 156 and the plurality of third pattern portions 158 disposed in the first part 151 of the metal plate 150, such that the plurality of patterns may not be visually recognized by the viewer.

In addition, the second part 152 of the metal plate 150 can include connection portions 115, the plurality of first opening portions 153, and the plurality of second opening portions 154.

Specifically, the second part 152 of the metal plate 150 can include the connection portions 115, the plurality of first opening portions 153, and the plurality of second opening portions 154 provided in the first bending area BA1 and the second bending area BA2.

In the second part 152 of the metal plate 150, the plurality of first opening portions 153 and the plurality of second opening portions 154 can be disposed to be spaced apart from one another.

The second part 152 of the metal plate 150 can have a shape in which the connection portions 115 are disposed between the plurality of first opening portions 153 and the plurality of second opening portions 154. The connection portions 115 of the second part 152 of the metal plate 150 can be integrated or connected with each other.

One end of the connection portion 115 can be connected to the first part 151 of the metal plate 150. Therefore, the first part 151 and the second part 152 of the metal plate 150 can be integrated with each other.

In the second part 152 of the metal plate 150, an area occupied by the plurality of first opening portions 153 and the plurality of second opening portions 154 can be larger than an area occupied by the connection portions 115.

As described above, the plurality of first opening portions 153 and the plurality of second opening portions 154 are disposed in the second part 152 of the metal plate 150, such that the metal plate 150 can be easily bent in the bending area BA.

In addition, the plurality of first opening portions 153 and the plurality of second opening portions 154 are disposed in the second part 152 of the metal plate 150, such that stress to be applied to the boundary between the first part 151 and the second part 152 of the metal plate 150 can be reduced, which can suppress the occurrence of a rapid change in rigidity of the metal plate 150.

In the metal plate 150 of the display device 100 according to the embodiment of the present disclosure, the first part 151 disposed in the non-bending area NBA includes the plurality of first pattern portions 156 and the plurality of third pattern portions 158, and the second part 152 disposed in the bending area BA includes the plurality of first opening portions 153 and the plurality of second opening portions 154, such that the first part 151 and the second part 152 can provide an effect of reducing the occurrence of stress at the boundary between the first part 151 and the second part 152.

The structure of the metal plate 150 of the display device 100 according to the embodiment of the present disclosure will be described specifically.

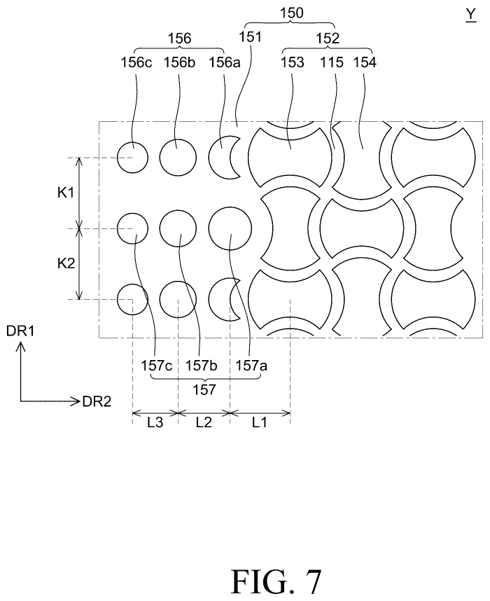

FIG. 7 is an enlarged view of area Y in FIG. 4.

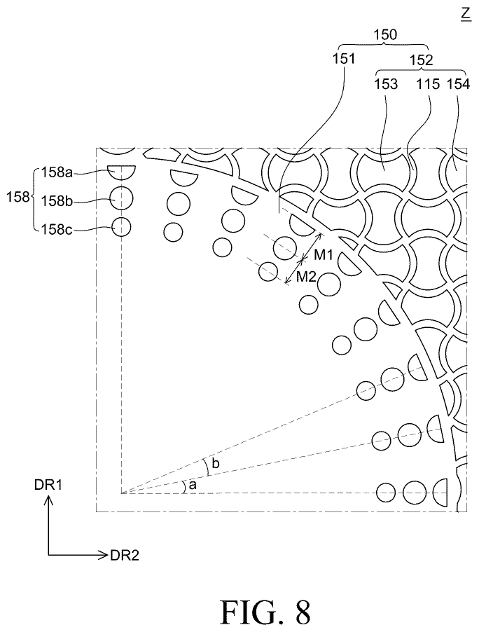

FIG. 8 is an enlarged view of area Z in FIG. 4.

With reference to FIGS. 7 and 8, the plurality of first pattern portions 156, the plurality of second pattern portions 157, and the plurality of third pattern portions 158 can be disposed in the first part 151 of the metal plate 150.

The first sub-pattern 156a of each of the plurality of first pattern portions 156 can be disposed between the second sub-pattern 156b and the first opening portion 153 disposed in the second part 152 of the metal plate 150.

A fourth sub-pattern 157a of each of the plurality of second pattern portions 157 can be disposed between a fifth sub-pattern 157b and the second opening portion 154 disposed in the second part 152 of the metal plate 150.

At least two of the first sub-pattern 156a, the second sub-pattern 156b, and the third sub-pattern 156c of each of the plurality of first pattern portions 156 and the fourth sub-pattern 157a, the fifth sub-pattern 157b, and a sixth sub-pattern 157c of each of the plurality of second pattern portions 157 can have different planar shapes.

Specifically, the planar shape of the first sub-pattern 156a disposed between the second sub-pattern 156b and the first opening portion 153 can vary depending on a planar shape of the first opening portion 153.

In addition, the planar shape of the fourth sub-pattern 157a disposed between the fifth sub-pattern 157b and the second opening portion 154 can vary depending on a planar shape of the second opening portion 154.

The planar shape of the first opening portion 153 can have an outer peripheral shape having two opposite sides convex in one direction and have an outer peripheral shape having two opposite sides concave in a direction intersecting one direction.

For example, as illustrated in FIG. 7, based on the plurality of first pattern portions 156, the planar shape of the first opening portion 153 disposed at one side of the first pattern portion 156 can have an outer peripheral shape convex in the second direction DR2 and have an outer peripheral shape concave in the first direction DR1.

Further, the planar shape of the first sub-pattern 156a disposed at one side of the first opening portion 153 can be an outer peripheral shape having a concave side surface that faces the first opening portion 153. The remaining area of the first sub-pattern 156a can have an outer peripheral shape convex in a plan view.

In other words, the planar shape of the first opening portion 153 can have a shape having a convex side surface that faces the first sub-pattern 156a, and the planar shape of the first sub-pattern 156a can have a shape having a concave side surface that faces the first opening portion 153. For example, the side surface of the first opening portion 153 facing the first sub-pattern 156a and the side surface of the first sub-pattern 156a facing the first opening portion 153 can correspond with each other, or complement each other.

As described above, with the relationship between the planar shapes of the first opening portion 153 and the first sub-pattern 156a, a degree to which compressive stress applied to the boundary between the first part 151 and the second part 152 is absorbed can be increased. In particular, the compressive stress applied between the first opening portion 153 and the first sub-pattern 156a can be reduced, which can reduce a change in rigidity in the area between the first opening portion 153 and the first sub-pattern 156a.

In addition, the planar shape of the second opening portion 154 can be a shape in which the first opening portion 153 is rotated by 90°.

Specifically, the planar shape of the second opening portion 154 can have a shape concave in one direction and have a shape convex in a direction intersecting one direction.

For example, as illustrated in FIG. 7, based on the plurality of second pattern portions 157, the planar shape of the second opening portion 154 disposed at one side of the second pattern portion 157 can have a shape concave in the second direction DR2 and have a shape convex in the first direction DR1.

In another aspect, one first opening portion 153 or one second opening portion 154 can be provided as two connection portions 115, which extend in one direction (e.g., the first direction DR1 or the second direction DR2), and two connection portions 115, which extend in another direction (the second direction DR2 or the first direction DR1) intersecting one direction, intersect one another.

Specifically, some of the plurality of connection portions 115 can extend in the first direction DR1, and some of the other connection portions 115 can extend in the second direction DR2.

The connection portion 115 extending in the first direction DR1 can have a line shape in which concave areas and convex areas are disposed alternately based on a straight line extending in the first direction DR1.

The connection portion 115 extending in the second direction DR2 can have a line shape in which concave areas and convex areas are disposed alternately based on a straight line extending in the second direction DR2. In other words, the connection portion 115 extending in the first direction DR1 or the second direction DR2 can have a wave shape or have a wavy configuration as shown in FIG. 7. In an example, the first pattern portions 156 (or the first sub-pattern 156a) can be disposed corresponding to the first opening portion 153 and align with the first opening portion 153 adjacent thereto, and the second pattern portions 157 (or the fourth sub-pattern 157a) can be disposed corresponding to the second opening portion 154 and align with the first opening portion 154 adjacent thereto.

In the area in which one first opening portion 153 is disposed, the two connection portions 115 extending in the first direction DR1 can each have a concave area, and the two connection portions 115 extending in the second direction DR2 can each have a convex area.

In addition, in the area in which one second opening portion 154 is disposed, the two connection portions 115 extending in the first direction DR1 can each have a convex area, and the two connection portions 115 extending in the second direction DR2 can each have a concave area.

Further, the planar shape of the fourth sub-pattern 157a disposed at one side of the second opening portion 154 can have a shape having a convex side surface that faces the second opening portion 154.

In other words, the planar shape of the second opening portion 154 can have a shape having a concave side surface that faces the fourth sub-pattern 157a, and the planar shape of the fourth sub-pattern 157a can have a shape having a convex side surface that faces the second opening portion 154. For example, the side surface of the second opening portion 154 facing the fourth sub-pattern 157a and the side surface of the fourth sub-pattern 157a facing the second opening portion 154 can correspond with each other, or complement each other.

As described above, with the relationship between the planar shapes of the second opening portion 154 and the fourth sub-pattern 157a, a degree to which compressive stress applied to the boundary between the first part 151 and the second part 152 is absorbed can be increased. In particular, the compressive stress applied between the second opening portion 154 and the fourth sub-pattern 157a can be reduced, which can reduce a change in rigidity in the area between the second opening portion 154 and the fourth sub-pattern 157a.

In addition, the second sub-pattern 156b, the third sub-pattern 156c, the fifth sub-pattern 157b, and the sixth sub-pattern 157c can each have a circular shape in a plan view.

However, the present disclosure is not limited thereto. The second sub-pattern 156b, the third sub-pattern 156c, the fifth sub-pattern 157b, and the sixth sub-pattern 157c can each have various shapes such as a semicircular shape, a semi-elliptical shape, or a polygonal shape.

In addition, a center of the first opening portion 153 disposed in the second part of the metal plate 150 can be disposed spaced apart, by a first distance L1, from a center of the first sub-pattern 156a of the first pattern portion 156 disposed at one side of the first opening portion 153.

In this case, the center of the first opening portion 153 can be a point at which a major axis and a minor axis of the first opening portion 153 intersect each other.

In addition, the center of the first sub-pattern 156a can refer to a point that is a center of an imaginary circular shape when the imaginary circular shape is defined based on the convex outer peripheral portion of the first sub-pattern 156a.

In this case, the first distance L1 can refer to a shortest straight distance from the center of the first opening portion 153 to the first sub-pattern 156a in a direction in which the sub-patterns included in the first pattern portion 156 are arranged.

In addition, the center of the first sub-pattern 156a can be spaced apart, by a second distance L2, from a center of the second sub-pattern 156b. The center of the second sub-pattern 156b can be spaced apart, by a third distance L3, from a center of the third sub-pattern 156c.

In this case, the center of the second sub-pattern 156b can refer to a center of a circular shape that is the planar shape of the second sub-pattern 156b, and the center of the third sub-pattern 156c can refer to a point that is a center of a circular shape that is the planar shape of the third sub-pattern 156c.

The second distance L2 can refer to a shortest straight distance from a center of a concave outer peripheral surface of the first sub-pattern 156a to the center of the second sub-pattern 156b in the direction in which the sub-patterns included in the first pattern portion 156 are arranged.

Further, the first distance L1 can be longer than the second distance L2 and the third distance L3. The second distance L2 can be longer than the third distance L3.

In other words, the first distance L1, the second distance L2, and the third distance L3 can gradually decrease.

For example, the second distance L2 and the third distance L3 can each be 12% to 25% shorter than the first distance L1.

In this case, in case that the second distance L2 and the third distance L3 are each decreased to a distance of more than 25% of the first distance L1, the intervals between the plurality of sub-patterns included in the first pattern portion 156 are decreased, which makes it difficult to perform a process of forming the sub-patterns. In addition, there can occur a problem in that the sizes of some of the sub-patterns are significantly decreased, compressive stress applied to the boundary between the first part 151 and the second part 152 of the metal plate 150 cannot be properly absorbed.

In addition, in case that the second distance L2 and the third distance L3 are each decreased to a distance of less than 12% of the first distance L1, it is difficult to form the plurality of sub-patterns in the limited pattern area PA, and some of the sub-patterns increase in sizes without being separated from one another because of the nature of the process, which can cause a problem in that some of the sub-patterns are visually recognized.

Therefore, the first sub-pattern 156a, the second sub-pattern 156b, and the third sub-pattern 156c included in the first pattern portion 156 are positioned at the boundary between the first part 151 and the second part 152 of the metal plate 150 and positioned in an area to which high compressive stress is applied.

As described above, because the first sub-pattern 156a, the second sub-pattern 156b, and the third sub-pattern 156c are positioned in the area to which high compressive stress is applied, it is possible to effectively absorb the compressive stress applied to the metal plate 150.

In addition, the plurality of patterns included in the second pattern portion 157 can have the same shape in a plan view. For example, the plurality of patterns of the second pattern portion 157 can each have a circular shape. The fourth sub-pattern 157a, the fifth sub-pattern 157b, and the sixth sub-pattern 157c included in the second pattern portion 157 can have different diameters.

For example, the diameter of the fourth sub-pattern 157a can be larger than the diameter of each of the fifth sub-pattern 157b and the sixth sub-pattern 157c. The diameter of the fifth sub-pattern 157b can be larger than the diameter of the sixth sub-pattern 157c.

Therefore, a distance between the center of the second opening portion 154 and the center of the fourth sub-pattern 157a, a distance between the center of the fourth sub-pattern 157a and the center of the fifth sub-pattern 157b, and a distance between the center of the fifth sub-pattern 157b and the center of the sixth sub-pattern 157c can be gradually decreased.

For example, magnitudes of the diameters of the plurality of patterns included in the second pattern portion 157 can be gradually decreased as a distance from the second part 152 of the metal plate 150 increases in one direction (e.g., the second direction DR2).

In this case, the diameter of each of the fifth and sixth sub-patterns 157b and 157c can be decreased to a diameter within a range of 16% to 30% of the diameter of the fourth sub-pattern 157a. However, the present disclosure is not limited thereto.

In this case, in case that the diameter of each of the fifth sub-pattern 157b and the sixth sub-pattern 157c is decreased to a diameter of more than 30% of the diameter of the fourth sub-pattern 157a, there can occur a problem in that the sizes of some of the sub-patterns included in the second pattern portion 157 are significantly decreased, compressive stress applied to the boundary between the first part 151 and the second part 152 of the metal plate 150 cannot be properly absorbed.

In addition, in case that the diameter of each of the fifth sub-pattern 157b and the sixth sub-pattern 157c is decreased to a diameter of less than 16% of the diameter of the fourth sub-pattern 157a, it is difficult to form the plurality of sub-patterns in the limited pattern area PA, and some of the sub-patterns increase in sizes without being separated from one another because of the nature of the process, which can cause a problem in that some of the sub-patterns are visually recognized.

As described above, the magnitudes of the diameters of the plurality of patterns included in the second pattern portion 157 are gradually decreased as the distance from the second part 152 of the metal plate 150 increases in one direction (e.g., the second direction DR2), such that the fourth sub-pattern 157a, the fifth sub-pattern 157b, and the sixth sub-pattern 157c included in the second pattern portion 157 can be positioned at the boundary between the first part 151 and the second part 152 of the metal plate 150 and positioned in the area to which high compressive stress is applied.

Furthermore, the fourth sub-pattern 157a, the fifth sub-pattern 157b, and the sixth sub-pattern 157c are not visually recognized, such that the visibility of the display device 100 can also be ensured.

In addition, a distance between at least one of the plurality of sub-patterns included in the first pattern portion 156 and at least one of the plurality of sub-patterns included in the second pattern portion 157 can be an equal interval.

Specifically, distances K1 and K2 between the third sub-pattern 156c, which is included in the first pattern portion 156, and the sixth sub-pattern 157c of the second pattern portion 157, which is disposed adjacent to the third sub-pattern 156c, can be maintained constantly.

For example, with reference to FIG. 7, the distance K1 from the center of one third sub-pattern 156c to the center of the adjacent sixth sub-pattern 157c can be equal to the distance K2 from the center of the sixth sub-pattern 157c to the center of another adjacent third sub-pattern 156c.

Therefore, at least some of the plurality of first pattern portions 156 and at least some of the plurality of second pattern portions 157 can be disposed at equal intervals.

Because at least some of the plurality of first pattern portions 156 and at least some of the plurality of second pattern portions 157 are disposed at equal intervals, it is possible to uniformly absorb the compressive stress applied to the boundary between the first part 151 and the second part 152 of the metal plate 150.

For example, in case that the area between the first part 151 and the second part 152 of the metal plate 150 has an area in which the plurality of first pattern portions 156 and the plurality of second pattern portions 157 are not disposed, compressive stress can be concentrated in the area in which the plurality of first pattern portions 156 and the plurality of second pattern portions 157 are not disposed, and the metal plate 150 can be wrinkled.

In contrast, in the metal plate 150 of the display device 100 according to the embodiment of the present disclosure, at least some of the plurality of first pattern portions 156 and at least some of the plurality of second pattern portions 157 are disposed at equal intervals, which can inhibit compressive stress from being concentrated in a particular area. In addition, it is to be noted that although the plurality of first pattern portions 156 and the plurality of second pattern portions 157 are described separately, the plurality of first pattern portions 156 and the plurality of second pattern portions 157 can have same configuration except for the sub-portions in the plurality of first pattern portions 156 and the plurality of second pattern portions 157 which are closest to the second part 152 of the metal plate 150 have different shapes or side surfaces. Accordingly, the plurality of first pattern portions 156 and the plurality of second pattern portions 157 can be collectively referred to as the plurality of pattern portions hereinafter.

In addition, with reference to FIG. 8, the plurality of third pattern portions 158 can each include the seventh sub-pattern 158a, the eighth sub-pattern 158b, and the ninth sub-pattern 158c. The seventh sub-pattern 158a, the eighth sub-pattern 158b, and the ninth sub-pattern 158c can be disposed to be spaced apart from one another in the direction between the first direction DR1 and the second direction DR2.

Some of the plurality of seventh sub-patterns 158a can be disposed between the first opening portions 153 and the eighth sub-patterns 158b.

Some of the other seventh sub-patterns 158a can be disposed between the second opening portions 154 and the eighth sub-patterns 158b.

Some of the remaining seventh sub-patterns 158a can be disposed between the connection portions 115 and the eighth sub-patterns 158b.

In addition, the planar shape of the seventh sub-pattern 158a can be different from the planar shape of each of the eighth sub-pattern 158b and the ninth sub-pattern 158c.

For example, the planar shape of the seventh sub-pattern 158a can be a semicircular shape, and the planar shape of each of the eighth sub-pattern 158b and the ninth sub-pattern 158c can be a circular shape.

A portion of the seventh sub-pattern 158a, which is convex in a plan view, can be disposed to be directed toward the eighth sub-pattern 158b. However, the present disclosure is not limited thereto.

In addition, in one third pattern portion 158 disposed in the metal plate 150, a distance M1 from the center of the seventh sub-pattern 158a to the center of the eighth sub-pattern 158b can be longer than a distance M2 from the center of the eighth sub-pattern 158b to the center of the ninth sub-pattern 158c.

For example, the distance M2 from the center of the eighth sub-pattern 158b to the center of the ninth sub-pattern 158c can be decreased to a distance within a range of 12% to 25% of the distance M1 from the center of the seventh sub-pattern 158a to the center of the eighth sub-pattern 158b.

In this case, the center of the seventh sub-pattern 158a can refer to a point that is a center of an imaginary circular shape when the imaginary circular shape is defined based on the convex outer peripheral portion of the seventh sub-pattern 158a.

In addition, the center of the eighth sub-pattern 158b can refer to a point that is a center of a circular shape that is the planar shape of the eighth sub-pattern 158b, and the center of the ninth sub-pattern 158c can refer to a point that is a center of a circular shape that is the planar shape of the ninth sub-pattern 158c.

Therefore, the magnitudes of the diameters of the seventh sub-pattern 158a, the eighth sub-pattern 158b, and the ninth sub-pattern 158c included in the third pattern portion 158 can be gradually decreased as the distance from the second part 152 of the metal plate 150 increases in the direction between the first direction DR1 and the second direction DR2.

For example, the diameter of each of the eighth and ninth sub-patterns 158b and 158c can be decreased to a diameter within a range of 16% to 30% of the diameter of the seventh sub-pattern 158a. However, the present disclosure is not limited thereto.

As described above, the magnitudes of the diameters of the plurality of patterns included in the third pattern portion 158 are gradually decreased as the distance from the second part 152 of the metal plate 150 increases in one direction (e.g., the direction between the first direction DR1 and the second direction DR2), such that the seventh sub-pattern 158a, the eighth sub-pattern 158b, and the ninth sub-pattern 158c can be positioned at the boundary between the first part 151 and the second part 152 of the metal plate 150 and positioned in the area to which high compressive stress is applied.

Furthermore, the seventh sub-pattern 158a, the eighth sub-pattern 158b, and the ninth sub-pattern 158c are not visually recognized, such that the visibility of the display device 100 can also be ensured.

In addition, the plurality of ninth sub-patterns 158c can be disposed at equal intervals.

Specifically, in case that the plurality of sub-patterns included in one third pattern portion 158 (hereinafter, referred to as a ‘first group’) disposed to be closest to the first bending area BA1 of the display device 100 are arranged in the first direction DR1 or the second direction DR2, the plurality of sub-patterns, which are included in another third pattern portion 158 (hereinafter, referred to as a ‘second group’) disposed to be closest to the first group, can be positioned on an imaginary line spaced apart from the first direction DR1 at angle a based on the second direction DR2.

In addition, the plurality of sub-patterns, which are included in another third pattern portion 158 disposed at one side of the second group disposed to be closest to the first group, can be positioned on an imaginary line spaced apart from the imaginary line, on which the plurality of patterns included in the second group are arranged, by angle b.

In this case, angle a and angle b can be equal to each other. In other words, the plurality of third pattern portions 158 are arranged in an equiangular distribution between the first direction DR1 and the second direction DR2 such that adjacent two third pattern portions 158 maintain identical angular intervals.

For example, angle a and angle b can each be within a range of 2° to 11.25°.

In case that angle a and angle b are each less than 2°, it is difficult to form the plurality of sub-patterns in the limited pattern area PA, and some of the sub-patterns increase in sizes without being separated from one another because of the nature of the process, which can cause a problem in that some of the sub-patterns are visually recognized.

In addition, in case that angle a and angle b are each more than 11.25°, compressive stress applied to the boundary between the second bending area BA2 and the non-bending area NBA of the metal plate 150 cannot be sufficiently absorbed, which can cause a defect of the metal plate 150.

As described above, the third pattern portions 158 of at least some of the plurality of third pattern portions 158 are disposed at equal intervals, such that it is possible to uniformly absorb the compressive stress applied to the boundary between the second bending area BA2 and the non-bending area NBA of the metal plate 150.

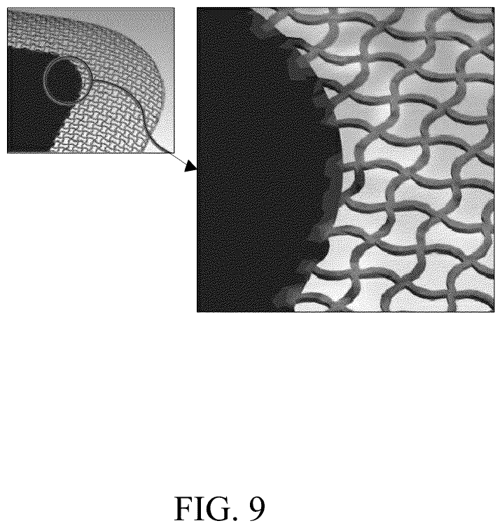

FIG. 9 is a view illustrating a change in rigidity applied to a boundary between a first part and a second part of a metal plate of a display device according to a comparative example.

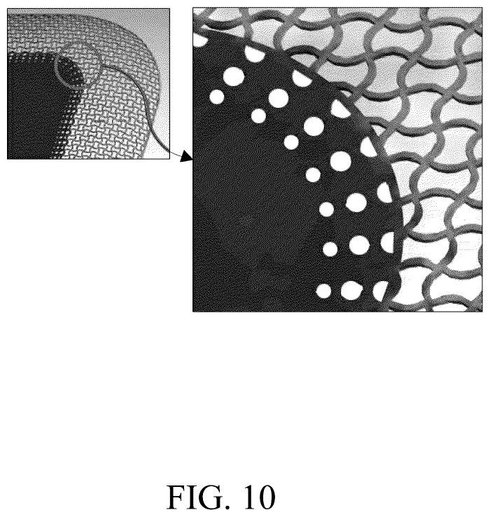

FIG. 10 is a view illustrating a change in rigidity applied to the boundary between the first part and the second part of the metal plate of the display device according to the embodiment.

The metal plate of the display device according to the comparative example has a structure in which the plurality of first pattern portions, the plurality of second pattern portions, and the plurality of third pattern portions are not disposed in the first part of the metal plate.

The metal plate 150 of the display device 100 according to the embodiment has the structure in which the plurality of first pattern portions 156, the plurality of second pattern portions 157, and the plurality of third pattern portions 158 are disposed in the first part 151 of the metal plate 150.

In FIGS. 9 and 10, the change in shadows in the non-bending area NBA adjacent to the bending area BA means that the rigidity changes.

With reference to FIG. 9, it can be seen that a rapid change in rigidity of the metal plate according to the comparative example occurs in the non-bending area NBA adjacent to the bending area BA.

The rapid change in rigidity of the metal plate causes a problem in which the shape of the metal plate is deformed.

In contrast, it can be seen that a gradual change in rigidity of the metal plate 150 according to the embodiment occurs in the non-bending area NBA adjacent to the bending area BA.

In this case, the occurrence of deformation of the metal plate 150 is remarkably reduced.

In other words, the plurality of first pattern portions 156, the plurality of second pattern portions 157, and the plurality of third pattern portions 158 are disposed at the boundary between the bending area BA and the non-bending area NBA of the metal plate 150, such that compressive stress to be applied to the boundary between the bending area BA and the non-bending area NBA can be reduced, which can suppress a defect in which the metal plate 150 is wrinkled.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope of the present disclosure thereof should be construed as falling within the scope of the present disclosure.

What is claimed is:

1. A display device comprising:
a display panel comprising a non-bending area and a bending area; and
a metal plate disposed below the display panel,
wherein the bending area comprises:
a first bending area corresponding to a lateral portion of the non-bending area; and
a second bending area corresponding to a corner portion of the non-bending area,
wherein the metal plate comprises:
a first part disposed in the non-bending area; and
a second part disposed in the bending area,
wherein a part of the first part of the metal plate includes a plurality of first pattern portions and a plurality of second pattern portions that are spaced apart from one another, and
wherein the second part of the metal plate includes a plurality of first opening portions and a plurality of second opening portions.

2. The display device of claim 1, wherein the first part of the metal plate further comprises a pattern area and a non-pattern area, and the pattern area is disposed between the non-pattern area and the second part of the metal plate.

3. The display device of claim 2, wherein the plurality of first pattern portions and the plurality of second pattern portions are disposed in the pattern area of the first part of the metal plate.

4. The display device of claim 1, wherein the first bending area is disposed at one side of the plurality of first pattern portions, and the second bending area is disposed at one side of the plurality of second pattern portions.

5. The display device of claim 4, wherein the plurality of first pattern portions comprise first sub-pattern portions and second sub-pattern portions, and the first sub-pattern portions and the second sub-pattern portions are disposed alternately.

6. The display device of claim 1, wherein each of the plurality of first pattern portions comprises:
a first sub-pattern spaced apart from a first opening portion among the plurality of first opening portions and disposed at one side of the first opening portion;
a second sub-pattern spaced apart from the first sub-pattern and disposed at one side of the first sub-pattern; and
a third sub-pattern spaced apart from the second sub-pattern and disposed at one side of the second sub-pattern.

7. The display device of claim 6, wherein in a plan view, a side surface of the first opening portion, which faces the first sub-pattern, has a convex shape, and a side surface of the first sub-pattern, which faces the first opening portion, has a concave shape.

8. The display device of claim 6, wherein the second sub-pattern and the third sub-pattern have a same planar shape.

9. The display device of claim 6, wherein a planar shape of each of the second sub-pattern and the third sub-pattern is different from a planar shape of the first sub-pattern.

10. The display device of claim 6, wherein a straight distance from a center of the first opening portion to a center of the first sub-pattern is longer than a straight distance from the center of the first sub-pattern to a center of the second sub-pattern and a straight distance from the center of the second sub-pattern to a center of the third sub-pattern.

11. The display device of claim 10, wherein a straight distance from the center of the first sub-pattern to the center of the second sub-pattern is longer than the straight distance from the center of the second sub-pattern to the center of the third sub-pattern.

12. The display device of claim 6, wherein in a plan view, a side surface of a second opening portion among the plurality of second opening portions, which faces the first sub-pattern, has a concave shape, and a side surface of the first sub-pattern, which faces the second opening portion, has a convex shape.

13. The display device of claim 12, wherein the first, second and third sub-patterns have a same planar shape.

14. The display device of claim 1, wherein the plurality of first pattern portions are disposed at equal intervals.

15. The display device of claim 1, wherein each of the plurality of second pattern portions comprises:
a fourth sub-pattern disposed to be closest to the second bending area;
a fifth sub-pattern spaced apart from the fourth sub-pattern and disposed at one side of the fourth sub-pattern; and
a sixth sub-pattern spaced apart from the fifth sub-pattern and disposed at one side of the fifth sub-pattern.

16. The display device of claim 15, wherein the fifth sub-pattern and the sixth sub-pattern have a same planar shape.

17. The display device of claim 15, wherein a planar shape of the fourth sub-pattern is different from planar shapes of the fifth and sixth sub-patterns.

18. The display device of claim 15, wherein a straight distance from a center of the fourth sub-pattern to a center of the fifth sub-pattern is longer than a straight distance from a center of the fifth sub-pattern to a center of the sixth sub-pattern.

19. The display device of claim 15, wherein the plurality of second pattern portions are disposed at equal intervals.
